(19) United States
(12) Patent Application Publication
(10) Pub. No.: US 2011/0316557 A1
(43) Pub. Date: Dec. 29, 2011

(54) TEST APPARATUS AND TEST METHOD

(75) Inventor: Keisuke WATANABE, Gunma (JP)

(73) Assignee: ADVANTEST CORPORATION, Tokyo (JP)

(21) Appl. No.: 13/163,765

(22) Filed: Jun. 20, 2011

Related U.S. Application Data
(63) Continuation of application No. PCT/JP2009/051370, filed on Jan. 28, 2009.

(51) Int. Cl. G01R 35/00

(52) U.S. Cl. 324/601

(57) ABSTRACT

A test apparatus that tests a device under test, comprising a signal output section that outputs a test signal for testing the device under test; a signal acquiring section that acquires a device signal output by the device under test; and an adjusting section that adjusts a signal output timing at which the signal output section outputs the test signal, according to a delay caused by a transmission path that connects the signal output section and the signal acquiring section to the device under test. The adjusting section includes a rising edge adjusting section that adjusts the signal output timing of a rising edge of the test signal based on a timing at which the signal acquiring section acquires a rising edge of a reflected signal resulting from a rising edge of an adjustment test signal output from the signal output section being reflected at an end of the transmission path on the device under test side; and a falling edge adjusting section that adjusts the signal output timing of a falling edge of the test signal based on a timing at which the signal acquiring section acquires a falling edge of a reflected signal resulting from a falling edge of the adjustment test signal output from the signal output section being reflected at the end of the transmission path on the device under test side.

### BACKGROUND

1. Technical Field

The present invention relates to a test apparatus and a test method.

2. Related Art

Conventionally, the difference between rising response and the falling response of a comparator in a test apparatus is detected and the timing of the comparator is adjusted based on the detected difference, as shown in Patent Document 1, for example.
Patent Document 1: Japanese Patent Application Publication No. 2008-107188

The method described in Patent Document 1 involves using a comparator to detect a waveform resulting from the reflection of an output waveform of a driver at an end of a transmission path that terminates in a ground potential, and adjusting the timing of the comparator based on the results. In order to accurately determine the timing of input and output signals of a device under test, it is necessary to adjust the timing at which the driver supplies the test signal. The output waveform of the driver has a difference between the rising time and the falling time, and therefore, in order to accurately adjust the timing, the timing is preferably adjusted while compensating for the difference between the rising time and the falling time.

### SUMMARY

Therefore, it is an object of an aspect of the innovations herein to provide a test apparatus and a test method, which are capable of overcoming the above drawbacks accompanying the related art. The above and other objects can be achieved by combinations described in the independent claims. The dependent claims define further advantageous and exemplary combinations of the innovations herein.

According to a first aspect related to the innovations herein, provided is a test apparatus that tests a device under test, comprising a signal output section that outputs a test signal for testing the device under test; a signal acquiring section that acquires a device signal output by the device under test; and an adjusting section that adjusts a signal output timing at which the signal output section outputs the test signal, according to a delay caused by a transmission path that connects the signal output section and the signal acquiring section to the device under test. The adjusting section includes a rising edge adjusting section that adjusts the signal output timing of a rising edge of the test signal based on a timing at which the signal acquiring section acquires a rising edge of a reflected signal resulting from a rising edge of an adjustment test signal output from the signal output section being reflected at an end of the transmission path on the device under test side; and a falling edge adjusting section that adjusts the signal output timing of a falling edge of the test signal based on a timing at which the signal acquiring section acquires a falling edge of a reflected signal resulting from a falling edge of the adjustment test signal output from the signal output section being reflected at the end of the transmission path on the device under test side.

According to a second aspect related to the innovations herein, provided is a test method for using a test apparatus to test a device under test, in which the test apparatus includes a signal output section that outputs a test signal for testing the device under test; a signal acquiring section that acquires a device signal output by the device under test; and a transmission path that connects the signal output section and the signal acquiring section to the device under test. The test method comprises adjusting a signal output timing of a rising edge of the test signal based on a timing at which the signal acquiring section acquires a rising edge of a reflected signal resulting from a rising edge of an adjustment test signal output from the signal output section being reflected at an end of the transmission path on the device under test side; and adjusting the signal output timing of a falling edge of the test signal based on a timing at which the signal acquiring section acquires a falling edge of a reflected signal resulting from a falling edge of the adjustment test signal output from the signal output section being reflected at the end of the transmission path on the device under test side.

The summary clause does not necessarily describe all necessary features of the embodiments of the present invention. The present invention may also be a sub-combination of the features described above.

### BRIEF DESCRIPTION OF THE DRAWINGS

FIG. 1 shows an exemplary configuration of a test apparatus 100 connected to a device under test 300 via a transmission path 200.

FIG. 2 shows an exemplary configuration of the signal output section 120.

FIG. 3 shows input/output waveforms of the signal output section 120.

FIG. 4A shows waveforms with ideal timings at the end of the transmission path 200 on the device under test 300 side.

FIG. 4B shows waveforms at the output end of the test apparatus 100 needed to achieve the waveforms shown in FIG. 4A.

FIG. 5 shows a waveform received by the signal acquiring section 140 when the end of the transmission path 200 on the device under test 300 side is an open end.

FIG. 6A shows an exemplary rising edge and an exemplary falling edge of a waveform output by the driver 124.

FIG. 6B shows the waveform received by the signal acquiring section 140 when the signal output section 120 outputs the waveform shown in FIG. 6A while the end of the transmission path 200 on the device under test 300 side is an open end.

### DESCRIPTION OF EXEMPLARY EMBODIMENTS

Hereinafter, some embodiments of the present invention will be described. The embodiments do not limit the invention according to the claims, and all the combinations of the features described in the embodiments are not necessarily essential to means provided by aspects of the invention.

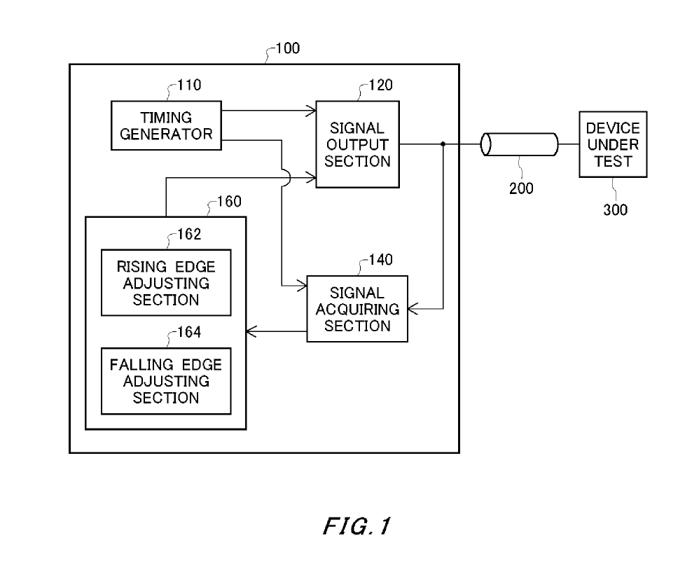

FIG. 1 shows an exemplary configuration of a test apparatus connected to a device under test 300 via a transmission path 200. The test apparatus includes a timing generator 110, a signal output section 120, a signal acquiring section 140, and an adjusting section 160. The test apparatus supplies the device under test 300 with a test signal and receives a device signal output by the device under test 300. The test apparatus 100 tests the device under test 300 based on the test signal and the device signal.

The timing generator 110 supplies the signal output section 120 with a timing signal that designates the timing at which the signal output section emits the test signal for testing the device under test 300. The timing generator 110 supplies the signal acquiring section 140 with a strobe signal that defines the timing at which the signal acquiring section 140 acquires the device signal output by the device under test 300.

The signal output section 120 outputs the test signal for testing the device under test 300, based on the timing signal supplied from the timing generator 110. The output end of the signal output section 120 is connected to the device under test 300 via the transmission path 200.

The signal acquiring section 140 acquires the device signal output by the device under test 300 via the transmission path 200. The signal acquiring section 140 may acquire the device signal at the timing defined by the strobe signal supplied from the timing generator 110. The signal acquiring section 140 may include a comparator that compares the magnitude of the voltage of the device signal to the magnitude of a prescribed threshold voltage, at the timing defined by the strobe signal supplied from the timing generator 110.

The adjusting section 160 adjusts the signal output timing at which the signal output section 120 outputs the test signal, according to a delay caused by the transmission path 200 that connects the device under test 300 to the signal output section 120 and the signal acquiring section 140. The adjusting section 160 includes a rising edge adjusting section 162 and a falling edge adjusting section 164. The rising edge adjusting section 162 adjusts the signal output timing of the rising edge of the test signal, based on the timing at which the signal acquiring section 140 acquires the rising edge of a reflected signal resulting from the rising edge of an adjustment test signal output from the signal output section 120 being reflected at the end of the transmission path 200 on the device under test 300 side. The falling edge adjusting section 164 adjusts the signal output timing of the falling edge of the test signal, based on the timing at which the signal acquiring section 140 acquires the falling edge of the reflected signal resulting from the falling edge of the adjustment test signal output from the signal output section 120 being reflected at the end of the transmission path 200 on the device under test 300 side.

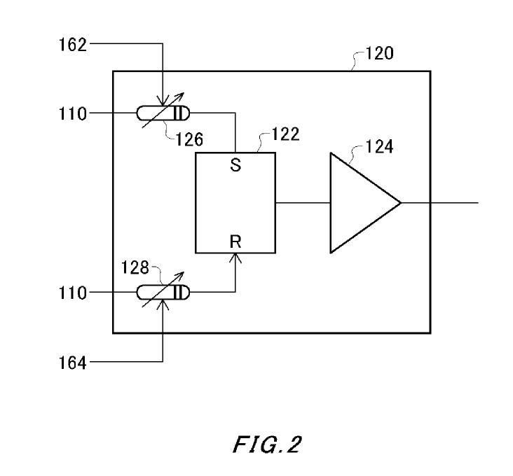

FIG. 2 shows an exemplary configuration of the signal output section 120. The signal output section 120 includes an SR flip-flop 122, a driver 124, a set-side variable delay section 126, and a reset-side variable delay section 128.

The SR flip-flop 122 outputs a test signal with logic H in response to a set signal being input thereto, and outputs a test signal with logic L when a reset signal is input thereto.

The driver 124 converts the test signal having logic H or logic L output from the SR flip-flop 122 into a prescribed voltage level, and outputs the converted test signal to the device under test 300.

The set-side variable delay section 126 changes a delay time, from when the timing signal indicating a rising edge of the test signal is received from the timing generator 110 to when the set signal is supplied to the SR flip-flop 122, according to a setting received from the rising edge adjusting section 162. The reset-side variable delay section 128 changes a delay time, from when the timing signal indicating a falling edge of the test signal is received from the timing generator 110 to when a reset signal is supplied to the SR flip-flop 122, according to a setting received from the falling edge adjusting section 164.

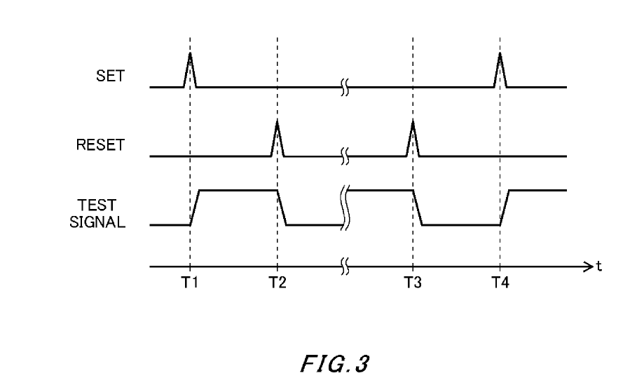

FIG. 3 shows input/output waveforms of the signal output section 120. When emitting a non-inverted pulse, the output of the signal output section 120 rises at the timing T1, which is a timing at which the timing signal indicating rising is received from the timing generator 110 as the set signal. Furthermore, the output of the signal output section 120 falls at the timing T2, which is a timing at which the timing signal indicating falling is received from the timing generator 110 as the reset signal. When emitting an inverted pulse, the output of the signal output section 120 falls at the timing T3, which is a timing at which the reset signal received from the timing generator 110 indicates falling of the test signal, and rises at the timing T4, which is a timing at which the set signal received from the timing generator 110 indicates rising of the test signal.

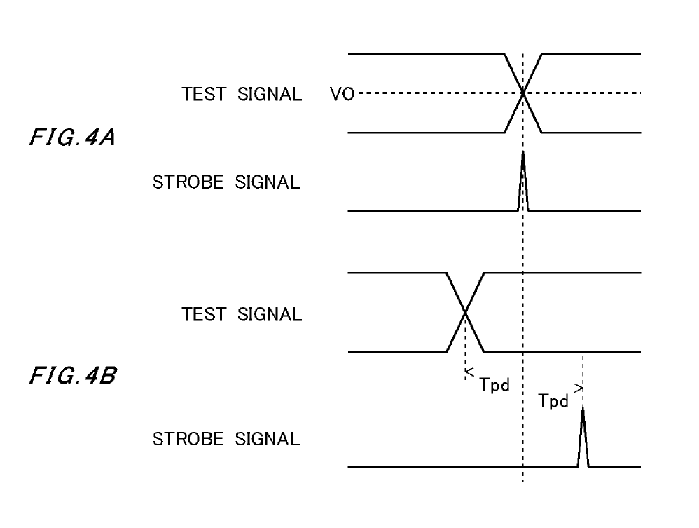

FIG. 4A shows waveforms with ideal timings at the end of the transmission path 200 on the device under test 300 side. At the end of the transmission path 200 on the device under test 300 side, the test signal output by the signal output section 120 with a reference timing setting and the strobe signal that designates the timing at which the signal acquiring section 140 acquires the device signal with a reference timing setting have the same edge timing, meaning they ideal, as shown in FIG. 4A. However, when a timing adjustment is performed that causes the timing relationship shown in FIG. 4A at the output end of the test apparatus 100, at the end of the transmission path 200 on the device under test 300 side, the test signal appears to be delayed relative to the ideal strobe signal by a propagation delay time (Tpd) of the transmission path 200 and the strobe signal appears to be ahead by the propagation delay time (Tpd).

Therefore, in order to obtain an ideal relationship for simultaneous input and output with the reference timing settings at the end of the transmission path 200 on the device under test 300 side, a timing relationship such as shown in FIG. 4B must be obtained at the output end of the test apparatus 100. In other words, the adjusting section 160 must adjust the edge timings such that the test signal is output from the signal output section 120 earlier by an amount equal to the propagation delay time (Tpd) of the transmission path 200 and the strobe signal is output after a time equal to the propagation delay time (Tpd) of the transmission path 200 has passed.

To adjust the timing in this manner, the propagation delay time (Tpd) of the transmission path 200 must be known. As an example, the signal acquiring section 140 may acquire the waveform resulting from the adjustment test signal output by the signal output section 120 being reflected at the end of the transmission path 200 on the device under test 300 side, and the propagation delay time (Tpd) of the transmission path 200 can be calculated from this acquired waveform. More specifically, the signal acquiring section 140 can acquire the waveform of the adjustment test signal at a plurality of strobe timings, detect transition points of the waveform, and obtain the propagation delay time (Tpd) of the transmission path 200 based on the intervals between the transition points.

When adjusting the edge timing of the test signal at the end of the transmission path 200 on the device under test 300 side, the end of the transmission path 200 on the device under test 300 side may be an open end. The adjusting section 160 may adjust the signal output timing at which the signal output section 120 outputs the test signal according to the delay amount of the reflected signal occurring when the end of the transmission path 200 on the device under test 300 side is an open end.

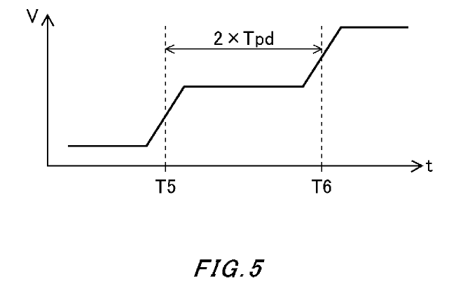

FIG. 5 shows a waveform received by the signal acquiring section 140 when the end of the transmission path 200 on the device under test 300 side is an open end. When the signal output section 120 outputs a rising edge of the adjustment test signal, the signal acquiring section 140 first receives the non-reflected edge, which is the rising edge of the waveform that directly reaches the signal acquiring section 140 from the signal output section 120 without passing through the transmission path 200 (T5). After this, the signal acquiring section 140 receives the reflected edge, which is the rising edge of the waveform that has returned to the signal acquiring section 140 as a result of the rising edge of the adjustment test signal arriving at the end of the transmission path 200 on the device under test 300 side and being reflected back to the signal acquiring section 140 (T6). Since the reflected edge travels back and forth across the transmission path 200 to arrive back at the signal acquiring section 140, the time from the arrival of the non-reflected edge to the arrival of the reflected edge corresponds to double the propagation delay time (Tpd) of the transmission path 200. Accordingly, the propagation delay time (Tpd) can be obtained from the waveform that has been reflected at the open end of the transmission path 200 on the device under test 300 side.

When adjusting the signal output timing at which the signal output section 120 outputs the test signal according to the delay of the reflected signal occurring when the end of the transmission path 200 on the device under test 300 side is an open end, the edges of the non-reflected wave and the reflected wave both return as rising edges, or both return as falling edges. Therefore, the timing of edges with the desired polarity can be adjusted, and so the timing can be accurately adjusted even when the signal acquiring section 140 has characteristics that depend on edge polarity.

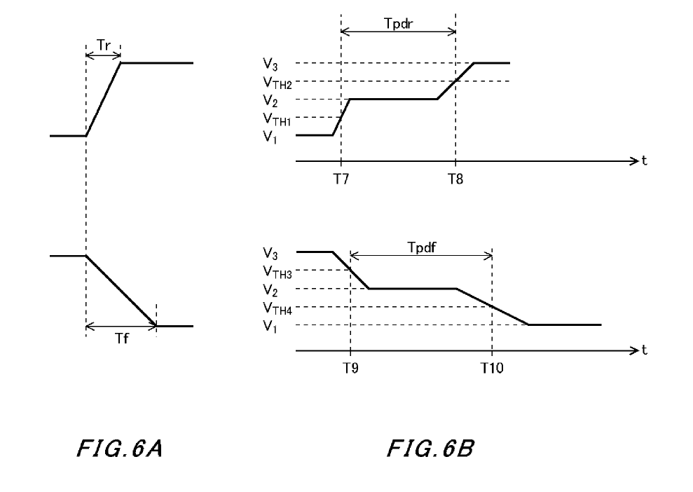

In some cases, the output waveform of the signal output section 120 can have a rising time Tr that differs from the falling time Tf. FIG. 6A shows an exemplary rising edge and an exemplary falling edge of a waveform output by the driver 124. FIG. 6B shows the waveform received by the signal acquiring section 140 when the signal output section 120 outputs the waveform shown in FIG. 6A while the end of the transmission path 200 on the device under test 300 side is an open end.

After the signal output section 120 outputs a rising edge, the signal acquiring section 140 detects the rising edge that arrives at the signal acquiring section 140 without passing through the transmission path 200 at the time T7, and detects the rising edge that is reflected at the end of the transmission path 200 on the device under test 300 side and arrives at the signal acquiring section 140 at the time T8. The time needed for the rising edge output by the signal output section 120 to travel back and forth across the transmission path 200 is T8 minus T7, and therefore the propagation delay time (Tpd) of the transmission path 200 calculated based on this rising edge is (T8−T7)/2.

In the same way, after the signal output section 120 outputs a falling edge, the signal acquiring section 140 detects the falling edge that arrives at the signal acquiring section 140 without passing through the transmission path 200 at the time T9, and detects the falling edge that is reflected at the end of the transmission path 200 on the device under test 300 side and arrives at the signal acquiring section 140 at the time T10. The time needed for the falling edge output by the signal output section 120 to travel back and forth across the transmission path 200 is T10 minus T9, and therefore the propagation delay time (Tpd) of the transmission path 200 calculated based on this falling edge is (T10−T9)/2.

When the falling time Tr of the output waveform of the signal output section 120 is different from the falling time Tf, the propagation delay time Tpdr calculated based on the falling edge differs from the propagation delay time Tpdf calculated based on the falling edge, as shown in FIG. 6B.

As a result, when performing the timing adjustment using a common propagation delay time for the rising edge and the falling edge, the timing relationship shown in FIG. 4A cannot be realized at the end of the transmission path 200 on the device under test 300 side. Therefore, in the present embodiment, an independent timing adjustment is performed for each of the rising edge and the falling edge.

The rising edge adjusting section 162 may adjust the signal output timing of the rising edge of the test signal, according to a difference between the timing at which the signal acquiring section 140 acquires the rising edge of the adjustment test signal and the timing at which the signal acquiring section 140 acquires the rising edge of the reflected signal resulting from the rising edge of the adjustment test signal being reflected at the end of the transmission path 200. The falling edge adjusting section 164 may adjust the signal output timing of the falling edge of the test signal, according to a difference between the timing at which the signal acquiring section 140 acquires the falling edge of the adjustment test signal and the timing at which the signal acquiring section 140 acquires the falling edge of the reflected signal resulting from the falling edge of the adjustment test signal being reflected at the end of the transmission path 200.

First, when adjusting the timing of the rising edge, the rising edge adjusting section 162 sets a first threshold voltage V_{TH1} for the signal acquiring section 140, and detects a first timing T7 at which the first threshold voltage V_{TF1} is crossed by the rising edge that occurs when the adjustment test signal output from the signal output section 120 transitions from a first voltage level V₁ below the first threshold voltage V_{TH1} to a second voltage level V₂ greater than the first threshold voltage V_{TH1}. Next, the rising edge adjusting section 162 sets a second threshold voltage V_{TH2} that is greater than the second voltage level V₂ for the signal acquiring section 140, and detects a second timing T8 at which the second threshold voltage V_{TH2} is crossed by a rising edge, which results from the rising edge occurring when the adjustment test signal from the signal output section 120 transitions from the first voltage level V₁ to the second voltage level V₂ being combined with the reflection of this rising edge from the end of the transmission path 200, of the transition from the second voltage level V₂ to a third voltage level V₃ that is greater than the second threshold voltage V_{TH2}. The rising edge adjusting section 162 adjusts the signal output timing of the rising edge of the test signal according to the rising edge propagation delay time Tpdr calculated as the difference between the first timing T7 and the second timing T8.

For example, the rising edge adjusting section 162 may set the propagation delay time of the transmission path 200 to be (T8−T7)/2 in the timing relationship shown in FIG. 6B, and may set the delay time of the set-side variable delay section 126 in a manner to adjust the signal output timing of the rising edge of the test signal to obtain the timing relationship shown in FIG. 4B at the output end of the test apparatus 100.

When adjusting the timing of the falling edge, the falling edge adjusting section 164 sets a third threshold voltage V_{TH3} that is between the second voltage level V₂ and the third voltage level V₃ for the signal acquiring section 140, and detects a third timing T9 at which the third threshold voltage V_{TH3} is crossed by the falling edge that occurs when the adjustment test signal output from the signal output section 120 transitions from the third voltage level V₃ to the second voltage level V₂. Next, the falling edge adjusting section 164 sets a fourth threshold voltage V_{TH4} that is between the first voltage level V₁ and the second voltage level V₂ for the signal acquiring section 140, and detects a fourth timing T10 at which the fourth threshold voltage V_{TH4} is crossed by a falling edge, which results from the falling edge occurring when the adjustment test signal from the signal output section 120 transitions from the third voltage level V₃ to the second voltage level V₂ being combined with the reflection of this falling edge from the end of the transmission path 200, of the transition from the second voltage level V₂ to the first voltage level V₁. The falling edge adjusting section 164 adjusts the signal output timing of the falling edge of the test signal according to the falling edge propagation delay time Tpdf calculated as the difference between the third timing T9 and the fourth timing T10.

For example, the falling edge adjusting section 164 may set the propagation delay time of the transmission path 200 to be (T10−T9)/2 in the timing relationship shown in FIG. 6B, and may set the delay time of the reset-side variable delay section 128 in a manner to adjust the signal output timing of the falling edge of the test signal to obtain the timing relationship shown in FIG. 4B at the output end of the test apparatus 100.

The first threshold voltage V_{TH1}, the second threshold voltage V_{TH2}, the third threshold voltage V_{TH3}, and the fourth threshold voltage V_{TH4} used when adjusting the timing of the rising edge and the falling edge may each have different voltage values. Instead, the first threshold voltage V_{TH1} may have the same voltage value as the fourth threshold voltage V_{TH4}, and the second threshold voltage V_{TH2} may have the same voltage value as the third threshold voltage V_{TH3}.

The rising edge adjusting section 162 and the falling edge adjusting section 164 may adjust the signal output timings of the rising edge and the falling edge of the test signal according to average values of the rising edge propagation delay time Tpdr and the falling edge propagation delay time Tpdf of the test signal in the transmission path 200.

The rising edge adjusting section 162 and the falling edge adjusting section 164 may adjust the signal output timing of the rising and falling edges of the test signal based on the timings at which the signal acquiring section 140 acquires the rising edge and the falling edge of the test reflection signal resulting from a rising edge and a falling edge in the same pulse of the adjustment test signal output by the signal output section 120 being reflected.

While the embodiments of the present invention have been described, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

What is claimed is:

1. A test apparatus that tests a device under test, comprising:
a signal output section that outputs a test signal for testing the device under test;
a signal acquiring section that acquires a device signal output by the device under test; and
an adjusting section that adjusts a signal output timing at which the signal output section outputs the test signal, according to a delay caused by a transmission path that connects the signal output section and the signal acquiring section to the device under test, wherein the adjusting section includes:
a rising edge adjusting section that adjusts the signal output timing of a rising edge of the test signal based on a timing at which the signal acquiring section acquires a rising edge of a reflected signal resulting from a rising edge of an adjustment test signal output from the signal output section being reflected at an end of the transmission path on the device under test side; and
a falling edge adjusting section that adjusts the signal output timing of a falling edge of the test signal based on a timing at which the signal acquiring section acquires a falling edge of a reflected signal resulting from a falling edge of the adjustment test signal output from the signal output section being reflected at the end of the transmission path on the device under test side.

2. The test apparatus according to claim 1, wherein
the adjusting section adjusts the signal output timing at which the signal output section outputs the test signal, according to a delay of the reflected signal occurring when the end of the transmission path on the device under test side is an open end.

3. The test apparatus according to claim 1, wherein
the rising edge adjusting section adjusts the signal output timing of the rising edge of the test signal, according to a difference between a timing at which the signal acquiring section acquires the rising edge of the adjustment test signal and the timing at which the signal acquiring section acquires the rising edge of the reflected signal resulting from the rising edge of the adjustment test signal being reflected at the end of the transmission path, and
the falling edge adjusting section adjusts the signal output timing of the falling edge of the test signal, according to a difference between a timing at which the signal acquiring section acquires the falling edge of the adjustment test signal and the timing at which the signal acquiring section acquires the falling edge of the reflected signal resulting from the falling edge of the adjustment test signal being reflected at the end of the transmission path.

4. The test apparatus according to claim 1, wherein the rising edge adjusting section:
sets a first threshold voltage for the signal acquiring section and detects a first timing at which the first threshold voltage is crossed by a rising edge that occurs when the adjustment test signal output by the signal output section transitions from a first voltage level that is less than the first threshold voltage to a second voltage level that is greater than the first threshold voltage,
sets a second threshold voltage that is greater than the second voltage level for the signal acquiring section and detects a second timing at which the second threshold voltage is crossed by a rising edge, which results from the rising edge occurring when the adjustment test signal from the signal output section transitions from the first voltage level to the second voltage level being combined with the reflection of this rising edge from the end of the transmission path, of a transition from the second voltage level to a third voltage level that is greater than the second threshold voltage, and
adjusts the signal output timing of the rising edge of the test signal according to a rising edge propagation delay time calculated as a difference between the first timing and the second timing.

5. The test apparatus according to claim 4, wherein the falling edge adjusting section:
sets a third threshold voltage that is between the second voltage level and the third voltage level for the signal acquiring section and detects a third timing at which the third threshold voltage is crossed by a falling edge that occurs when the adjustment test signal output from the signal output section transitions from the third voltage level to the second voltage level,
sets a fourth threshold voltage that is between the first voltage level and the second voltage level for the signal acquiring section and detects a fourth timing at which the fourth threshold voltage is crossed by a falling edge, which results from the falling edge occurring when the adjustment test signal from the signal output section transitions from the third voltage level to the second voltage level being combined with the reflection of this falling edge from the end of the transmission path, of a transition from the second voltage level to the first voltage level, and
adjusts the signal output timing of the falling edge of the test signal according to a falling edge propagation delay time calculated as a difference between the third timing and the fourth timing.

6. The test apparatus according to claim 5, wherein
the rising edge adjusting section and the falling edge adjusting section adjust the signal output timings of the rising edge and the falling edge of the test signal according to average values of the rising edge propagation delay time and the falling edge propagation delay time in the transmission path.

7. The test apparatus according to claim 1, wherein
the rising edge adjusting section and the falling edge adjusting section adjust the signal output timings of the rising edge and the falling edge of the test signal based on the timings at which the signal acquiring section acquires the rising edge and the falling edge of the reflected signal resulting from the reflection of the rising edge and the falling edge in the same pulse of the adjustment test signal output from the signal output section.

8. The test apparatus according to claim 1, wherein the signal output section includes:
an SR flip-flop that outputs a test signal with logic H in response to a set signal being input thereto and outputs a test signal with logic L in response to a reset signal being input thereto;
a set-side variable delay section that changes a delay time that is from when instructions causing the test signal to rise are received to when the set signal is supplied to the SR flip-flop, according to a setting from the rising edge adjusting section; and
a reset-side variable delay section that changes a delay time that is from when instructions causing the test signal to fall are received to when the reset signal is supplied to the SR flip-flop, according to a setting from the falling edge adjusting section.

9. A test method for using a test apparatus to test a device under test, wherein the test apparatus includes:
a signal output section that outputs a test signal for testing the device under test;
a signal acquiring section that acquires a device signal output by the device under test; and
a transmission path that connects the signal output section and the signal acquiring section to the device under test, the test method comprising:
adjusting a signal output timing of a rising edge of the test signal based on a timing at which the signal acquiring section acquires a rising edge of a reflected signal resulting from a rising edge of an adjustment test signal output from the signal output section being reflected at an end of the transmission path on the device under test side; and
adjusting the signal output timing of a falling edge of the test signal based on a timing at which the signal acquiring section acquires a falling edge of a reflected signal resulting from a falling edge of the adjustment test signal output from the signal output section being reflected at the end of the transmission path on the device under test side.
